(19) United States
(12) Patent Application Publication
(10) Pub. No.: US 2011/0027928 A1
(43) Pub. Date: Feb. 3, 2011

(54) PULSED LASER DEPOSITION OF HIGH QUALITY PHOTOLUMINESCENT GaN FILMS

(75) Inventors: JEONGGOO KIM, LAUREL, MD (US); SOLOMON HARSHAVARDHAN KOLAGANI, ELLICOTT CITY, MD (US); MIKHAIL STRIKOVSKI, ROCKVILLE, MD (US)

Correspondence Address: ROSENBERG, KLEIN & LEE, 3458 ELLICOTT CENTER DRIVE-SUITE 101, ELLICOTT CITY, MD, 21043, US

(73) Assignee: NEOCERA, LLC, BELTSVILLE, MD (US)

(21) Appl. No.: 12/905,237

(22) Filed: Oct. 15, 2010

Related U.S. Application Data
(62) Division of application No. 11/783,439, filed on Apr. 10, 2007.

(51) Int. Cl. H01L 33/32

(52) U.S. Cl. 438/46; 257/E33.025

(57) ABSTRACT

High quality GaN films exhibiting strong room temperature blue photoluminescence with negligible impurity emissions are grown by a Pulsed Laser Deposition process in which process parameters are controlled to attain plasma particle energy of a target material plume directed from the target on the substrate structure below 5 eV at the deposition surface. Among the process parameters, a distance between the deposition surface and the target, a pressure level of the reaction gas in the processing chamber, and an energy density of the pulsed laser beam directed to the target are controlled, in combination, to attain the required low plasma particle energy of the plume below 5 eV in vicinity of the deposition surface.

### RELATED APPLICATIONS

This application is a Divisional patent application of co-pending application Ser. No. 12/783,439, filed on 10 Apr. 2007. The entire disclosure of the prior application, Ser. No. 12/783,439, from which an oath or declaration is supplied, is considered a part of the disclosure of the accompanying Divisional application and is hereby incorporated by reference.

### FIELD OF THE INVENTION

The present invention relates to the field of opto-electronics; and more in particular to fabrication of high quality GaN films.

The present invention is further related to Pulsed Laser Deposition processes for fabrication of high quality GaN films which demonstrate strong blue photoluminescence at room temperature with negligible impurity emission in other spectrum regions.

The present invention is further directed to a Pulsed Laser Deposition process for fabrication of high quality GaN films fabricated by maintaining the plasma particle energy of the deposition material at the deposition surface below 5 eV.

### BACKGROUND OF THE INVENTION

Gallium nitride (GaN) is considered as one of the most promising materials for optoelectronic applications due to its blue light emission, wide band gap and ability to withstand high temperatures in hostile environments.

A variety of deposition techniques applicable for fabrication of GaN films include Chemical Vapor Deposition (CVD), Molecular Beam Epitaxy (MB), Vapor Phase Epitaxy (VPE), Sputtering (SP), as well as Pulsed Laser Deposition (PLD). The PLD technology permits ease of material handling for versatile spectrum of materials and is advantageous as it produces pulsed plumes having high kinetic energy. Unfortunately, GaN films previously fabricated by the Pulsed Laser Deposition have not demonstrated a photoluminescence of a sufficient quality. Most GaN films resulting from Pulsed Laser Deposition provide photoluminescence at low temperatures (approximately 12K) as presented in M. Cazzanelli, et al., “Photoluminescence of Localized Excitons in Pulsed-Laser-Deposited GaN”, Applied Physics Letters, Volume 73, Number 23, 7 Dec. 1998, pages 3390-3392, and M. Cazzanelli, et al., “Luminescent Properties of GaN Thin Films Prepared by Pulsed Laser Deposition”, Materials Science & Engineering, B59 (1999), pages 137-140.

When being investigated at temperature above 12K, the pulsed laser deposited GaN films have demonstrated intensive impurities emission in the yellow band width area of the spectrum, as presented in S. Ito, et al. “Effect of AlN Buffer Layers on GaN/MnO Structure”, Phys. Stat. Sol. (c) 0, 1, pages -192-195 (2002). Despite extensive research efforts, fabrication of photoluminescenting GaN films of a high quality fabricated by PLD process have not been attained.

It thus is desirable to manufacture GaN films exhibiting a well defined strong emission in the blue spectrum at room temperature without intensive yellow light emission by the PLD process.

### SUMMARY OF THE INVENTION

It is an object of the present invention to provide a method for Pulsed Laser Deposition of high quality GaN films exhibiting a well-defined strong room temperature blue photoluminescence without significant impurity emissions.

It is a further object of the present invention to provide a PLD method for fabricating GaN films in which process parameters are balanced to attain and maintain favorable conditions permitting the growth of high quality GaN films.

It is still another object of the present invention to provide a system for Pulsed Laser Deposition of high quality GaN films exhibiting strong blue photoluminescence with negligible impurities emissions which includes a control unit for balancing a multiplicity of process parameters in order to maintain plasma particle energy of the plume of the target material below 5 eV at the deposition surface which has been found to be an important condition for manufacturing high quality GaN films.

A method for pulsed laser deposition of high quality GaN films comprises the steps of:

positioning a substrate structure in a processing chamber,

positioning a target in the processing chamber a predetermined distance from the deposition surface of the substrate structure,

focusing a pulsed laser beam of a predetermined energy density on the target to ablate the target material therefrom, thereby forming a plume of the target material directed towards the deposition surface resulting in deposition of the GaN film thereon, and

controlling the process parameters, such as, for example, (1) the distance between the deposition surface and the target, (2) predetermined pressure level of the reaction gas in the processing chamber, (3) energy density of the pulsed laser beam, and (4) ablation area to maintain plasma particle energy of the plume of the target material below a predetermined energy level at the deposition surface.

The processing parameters of the PLD process are controlled to balance the same for the purpose of attaining plasma energy at the deposition surface below 5 eV.

The present invention also is a system for Pulsed Laser Deposition of high quality GaN films which includes a processing chamber filled with a reaction gas, a substrate structure positioned in the processing chamber, a target located in the processing chamber a predetermined distance from the substrate structure, a laser unit generating a pulsed laser beam, a focusing mechanism focusing the pulsed laser beam on the target to ablate the target material therefrom for forming a plume of the target material directed toward the substrate structure to coat the GaN film thereon. A control unit controls the process parameters to attain and to maintain plasma energy of the plume of the target material below 5 eV at the deposition surface of the substrate structure.

The substrate structure includes a substrate formed, for example, from Al₂O₃, and a buffer layer formed from AlN on the top of the substrate.

These and other features and advantages of the present invention will be apparent from the further description when taken in conjunction with the patent drawings.

### BRIEF DESCRIPTION OF THE PATENT DRAWINGS

FIG. 1 is a schematic representation of the system of the present invention for Pulsed Laser Deposition of GaN films;

FIG. 2 is a schematic representation of GaN films grown on a substrate structure containing Al₂O₃ substrate and AlN buffer layer;

FIG. 3 is a diagram representing 2θ-θ scan for GaN film;

FIGS. 4A and 4B are diagrams representing ω-scan for (0002) GaN film and ω-scan for (0002) AlN buffer layer, respectively;

FIGS. 5A-5C are diagrams representing φ-scans of GaN (10 1̅1) peak, AlN (10 1̅1) peak, Al₂O₃ (11 2̅3) peak, respectively, at the plasma energy below 5 eV; and

FIG. 6 is a diagram representing a photoluminescence spectrum of the GaN film measured at room temperature.

### DESCRIPTION OF THE PREFERRED EMBODIMENT OF THE PRESENT INVENTION

Pulsed Laser Deposition (PLD) is a thin film deposition technique using a power pulsed laser beam focused within a vacuum chamber to strike a target having a desired composition. Material is vaporized from the target and is deposited as a thin film on a substrate. This process may occur in an ultra high vacuum or in the presence of a reaction gas. When the laser pulse is absorbed by the target, energy is first converted to electronic excitation and then into thermal, chemical and mechanical energy resulting in evaporation, ablation, plasma formation and acceleration o high kinetic energy away from the target.

The ejected species expand into the surrounding vacuum (or reaction gas atmosphere) in the form of a plume containing energetic species including atoms, molecules, electrons, ions, clusters, particulates and molten globules before being deposited on a typically hot substrate. The PLD process is generally divided into stages of laser ablation of the target material, creation of plasma, deposition of the ablation material on the substrate, and nucleation and growth of the film on the substrate surface. Each of these steps is important for the crystallinity, properties and stoichiometry of the resulting film.

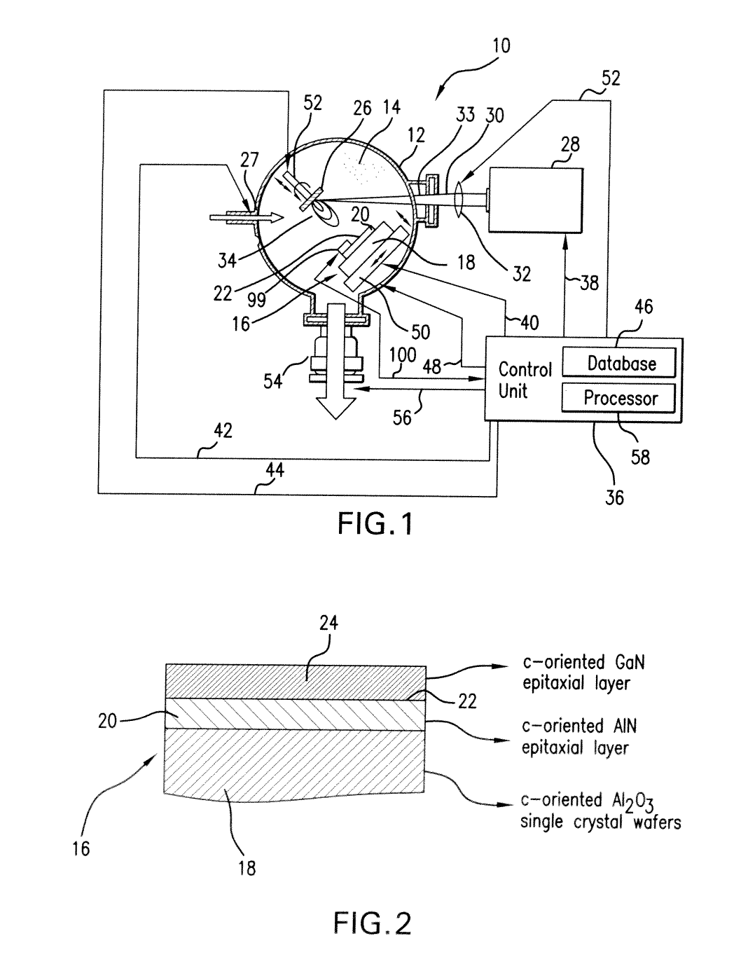

Referring to FIG. 1, a system 10 for Pulsed Laser Deposition is shown which includes a processing chamber 12 filled with a reaction gas 14. A substrate structure 16 is positioned on a substrate holder 50 which may be controlled by a motion control mechanism (not shown) to cause rotational, angular and/or reciprocal linear motion of the substrate structure in several directions as is well known to those skilled in the art.

The substrate structure 16 as best shown in FIG. 2 includes a substrate 18 and a buffer layer 20 grown on the substrate 18. The substrate may be formed from a c-axis oriented Al₂O₃ substrate, while the buffer layer may be manufactured from a c-axis oriented AlN buffer layer. It is apparent to those skilled in the art that other materials may also be used for the substrate 18 and the buffer layer 20.

Although a variety of deposition techniques may be applicable for forming the buffer layer 20 on the surface of the substrate 18, it is preferred that the buffer layer 20 be deposited on the substrate 18 by Pulsed Laser Deposition. After surface cleaning of the substrate 18 with ethanol and acetone, the substrate is introduced into the PLD processing chamber 12. After heating the substrate, a laser ablates a hot pressed AlN target to permit growth of the AlN buffer layer to a thickness of approximately 20-100 nm in ambient atmosphere. The substrate temperature and reaction gas pressure for the growth of the buffer layer are 800-1000° C. and 0.1-5 mTorr, respectively. After the buffer layer 20 is grown on the substrate 18, GaN film is grown on a deposition surface 22 defined as the upper surface of the buffer layer 20.

In order to grow GaN film 24, a target 26 is installed in the processing chamber 12 a predetermined distance from the substrate structure 16. The target 26 is supported by a target holder 52 which may be operationally coupled to a motion control mechanism (not shown) capable of causing rotational, angular, and/or reciprocal linear motion of the target in several directions, as known to those skilled in the art. The target 26 is preferably formed from Ga, or GaN ceramics. For heating the substrate, a heater (not shown) is provided in proximity thereto, which preferably is a heating element in modular implementation with the substrate holder.

A reaction gas 14, which may be N₂, ammonia, or their mixture, is introduced into the processing chamber 12 through an inlet 27 and maintained at a controlled pressure during the growth of the GaN film.

A laser unit 28 generates a pulsed laser beam 30 of the controlled laser energy density which is focused on the target 26 by a focusing mechanism 32 which may be adapted to control the cross-section of the laser beam, as well as the direction thereof. The focusing mechanism 32 may include a UV quality optical lens and/or mirrors for directing the laser beam onto the target through a UV quality window 33 provided at the flange of the processing chamber 12. The focusing mechanism 32 is also used for focusing the beam 30 to attain a required size of the beam cross-section on the target surface. Further, the focusing mechanism 32 may be controlled (manually or electronically) to create a motion of the laser beam 30 relative the target surface and adjust an angular relative disposition therebetween.

A wide range of pulsed lasers capable of producing a sufficient power to create a beam of a needed energy density may be used. For example, an Excimer laser may be utilized in the system of the present invention. When the target 26 is exposed to the laser beam 30 having sufficient energy density capable of ablating the target material therefrom, a target material plume 34 is formed which emanates from the target 26 in the direction of the deposition surface 22 of the substrate structure 16.

During ablation of the target material upon laser irradiation, the removal of atoms from the bulk target material is accomplished by vaporization of the material at the surface region in a non-equilibrium state. The incident laser pulse penetrates into the surface of the target material within the penetration depth, which is dependent on the laser wavelength and the index of refraction of the target material at the applied laser wavelength.

The electrical field generated by the laser light is sufficiently strong to heat the electrons in the bulk material of the penetrated volume. This process is also enhanced by non-linear processes such as multiphoton ionization. The free electrons oscillate within the electromagnetic field of the laser light and collide with the atoms of the bulk material thus transferring some of their energy to the lattice of the target material within the surface region. The surface of the target is then heated up and the material is vaporized.

The target material(s) emanating from the target 26 is(are) transferred to the deposition surface 22 in highly energetic plasma state. In this stage, the material expands as plasma towards the substrate. The spatial distribution of the plume is dependent on the gas pressure inside the PLD chamber and may influence the stoichiometry of the deposited film.

When the ablated materials reach the deposition surface 22, they are deposited thereon, thereby forming a GaN film 24. This stage is important for the quality of the deposited films. The high energetic species ablated from the target are bombarding the substrate surface and may cause damage to the surface by sputtering atoms from the surface but also by causing defect formations in the deposited film. The particles emitted from the target form a collision region, which serves as a source for condensation of particles on the deposition surface. When the condensation rate of the direct flow of ablation particles is high, thermal equilibrium is not reached and the film can be degraded.

The nucleation process and growth of crystalline film on a substrate depend on several factors such as the density, energy and ionization degree of the ablated materials as well as temperature, roughness and crystalline properties of the substrate. In order to obtain a high quality GaN film 24, process deposition process parameters are controlled by means of a control unit 36 which is schematically presented in FIG. 1. The process parameters may include temperature of the substrate structure, chamber gas pressure, chamber gas type, target-to-substrate distance, laser energy density, deposition rate, etc.

It has been found in the PLD process of the present invention that by maintaining the plasma energy of the plume 34 of the target material at the deposition surface 22 below 5 eV, high quality GaN films may be produced which exhibit strong well defined blue photoluminescence with negligible impurity emission. In order to maintain the plasma energy of the target material plume at the deposition surface below 5 eV, it is required to balance a combination of the process parameters which mainly include for these purposes the energy density of the laser beam 30, pressure of the reaction gas 14 in the processing chamber 12, and target-substrate structure distance.

An ion probe 99 may be equipped at or in proximity to the substrate position to measure the ion current I(t) driven by the plasma with respect to the time. This measured ion current I(t) can be converted into the energy which is below 5 eV for the best quality GaN films, using a model describing plasma deceleration in background gases presented in M. Strikovski and J. Miller: Pulsed laser deposition of oxides: Why the optimum rate is about 1 Å per pulse, Appl. Phys. Lett., 73 (1998) 1733. Once the optimized ion current I(t) at the substrate position is found for GaN film process, which is below 5 eV, the process parameters may be modified while keeping the optimized plasma energy below 5 eV, at the substrate position.

For example, as the target-to-substrate distance decreased, the amplitude of I(t) signal increases, and the delay time (t) of the signal decreases. In order to bring down the increased ion energy below 5 eV at the decreased target-to-substrate distance, the gas pressure may be increased or the laser energy may be decreased.

Alternatively, if the process requires a very high laser energy, increasing the target-to-substrate distance or the background gas pressure will compensate the increased ion energy.

Also, the background gas pressure may be set first, and the target-to-substrate distance and the laser beam energy can be adjusted to keep the plasma energy below 5 eV at the substrate position. Once the ranges of the identified process parameters have been established for maintaining the plasma energy below 5 eV, the ion probe 99 may be removed. The process parameters are stored in the control unit 36 thought the communication channel 100 to be used by the control unit 36 to control the PLD process.

The control unit 36 may set the target-to-substrate distance to be large enough to reduce the plume energy at the deposition surface. For example, if the target-to-substrate distance exceeds 6 inches, the control unit 36 may set the laser unit 28 to produce the laser beam with an energy density falling in the range of 2-8 J/cm². The process pressure then is maintained within 5-100 mTorr.

However, even at shorter distances, for example, about less than 4 inches, the plasma energy can be lower than 5 eV when the pressure of the reaction gas is high enough to suppress the energy of the plume at the deposition surface with proper laser beam energy on the target surface. For example, in an alternative arrangement, for the distance between the target and the deposition surface below or approximately 4 inches or less, the pressure level of the reaction gas in the processing chamber may be maintained approximately higher than 50 mTorr, while the energy density of the pulsed laser beam falls in the range of less than 1.5 J/cm².

But even at relatively higher pressure ranges, it is possible to attain plasma energy of the plume below 5 eV by reducing the laser beam energy at a short distance. For example, in another alternative arrangement, where the distance between the target and the deposition surface is set in the range of 4-6 inches, the pressure level of the reaction gas in the processing chamber may be maintained in the range of 30-150 mTorr, and the energy density of the pulsed laser beam may be maintained approximately at 1-4 J/cm².

The control unit 36 finds the combination of the process parameters which results in the low plasma energy <5 eV, and sets these three processing parameters, e.g., the distance between the target and the deposition surface, the reaction gas pressure in the processing chamber 12, and the energy density of the pulsed laser beam directed towards the target 26 to provide a low plasma energy of the plume 34 below 5 eV at the deposition surface 22, and to maintain this plasma energy level during the deposition process.

The control unit 36 may also control the temperature in the processing chamber, specifically the temperature of the substrate structure to be within the range of ˜400-900° C. to provide high quality crystal structures for the GaN films. The control unit 36 also controls the deposition rate which may be maintained below 0.2 Å per pulse with proper laser beam spot sizes on the target.

Table 1 shows Pulse Laser Deposition process parameters for GaN film growth for different alternative arrangements.

### Pulsed Laser Deposition Parameters for GaN Films

TABLE 1

| | | | |
|---|---|---|---|
| Plasma energy on | <5 | <5 | <5 |
| substrate, eV | | | |
| Process Pressure, | >50 | 30-150 | 5-100 |
| mTorr | | | |
| Target-Substrate | <4 | 4-6 | >6 |
| Distance, inch | | | |
| Beam Energy | >1.5 | 1-4 | 2-8 |
| Density, J/m² | | | |
| Deposition Rate, | <0.2 | <0.2 | <0.2 |
| Å/pulse | | | |
| Temperature, ° C. | 400-900 | 400-900 | 400-900 |

It is clear to those skilled in the art that other combinations of target distance, process pressure and energy density of the laser beam are also possible as long as the plasma energy on the deposition surface below 5 eV is maintained during the deposition process in accordance with the teaching of the present invention.

GaN films grown by the Pulsed Laser Deposition process of the present invention, where the plasma energy of the plume of the target material is maintained below 5 eV at the deposition surface have been tested. They exhibited excellent crystal structure characteristics as well as strong and well-defined blue photoluminescence. Negligible impurity emission has been observed for the GaN films.

The combination of the process parameters which may result in the plasma below 5 eV has been determined as the result of thorough theoretical studies and experimentation. The results have been stored as a database 46 in the control unit 36 or at an independent memory medium (block) coupled to the control unit 36. The data may also be presented in the form of look-up tables, or alternatively n the form of graphics and diagrams representative of the relationships between the process parameters, which, if maintained during the PLD, result in the required plasma density below 5 eV which is important for growing high quality GaN film. The Control Unit 36 uses the data stored therein or in an independent memory block and controls the process parameters correspondingly.

The Control Unit 36 is operationally coupled to the essential portions of the system 10 through a set of control channels to monitor and adjust the process parameters, as well as to provide a smooth functioning of systems 10 resulting in high quality GaN films. The control unit 36 is connected to the laser 28 through a channel 38 to control the operation of the laser, including the energy density of the generated laser beam 30, pulse repetition, pulse width, pulse amplitude, etc.

In order to control the distance between the target 26 and the substrate structure 16, the control unit 36 is operationally coupled to the substrate holder 50 and/or the target holder 52 to change a relative disposition therebetween by means of controlling target and/or substrate holders motion mechanisms (not shown) through channels 40 and/or 44, respectively. The motion mechanisms may include linear and rotational motors providing several degrees of freedom. These motion mechanisms are well known to those skilled in the art, and therefore are not described herein in further detail. The target 26, as well as the substrate structure 16, are therefore capable of rotational, angular and reciprocal linear motion under the control of the unit 36.

In order to control the gas pressure within the processing chamber 12, the control unit 36 issues control signals which are supplied to the gas inlet 27 and pumping system 54 through channels 42 and 56, respectively, in order to attain and/or adjust the gas pressure to a needed level.

The control unit 36 may also control other process parameters, such as for example, the temperature through a channel 48 which communicates t° control signals to the substrate heater (not shown), which may be disposed in proximity to the substrate, preferably, at the holder 50.

Additionally, the control unit 36 is coupled to the focusing mechanism 32 through a control channel 52 to control optical characteristics of the beam 30, as well as the direction of its propagation by manipulating the optics (UV lens) of the mechanism 32.

The control unit 36 further includes a processor 58 which dynamically processes information acquired by the unit 36 during the manufacturing process, consults with the data-base 46, and issues control signals representative of actions to be taken by the system 10 to maintain the plume energy below 5 eV at the deposition surface 22. The data-base 46, as was presented in previous paragraphs, may include experimental data representative of relationships of the process parameters with the plume energy, and/or an algorithm which is based on the theoretical interpretation of the physics of the PLD process and which is developed to determine the process parameters resulting in combination, in the required plume energy level below 5 eV.

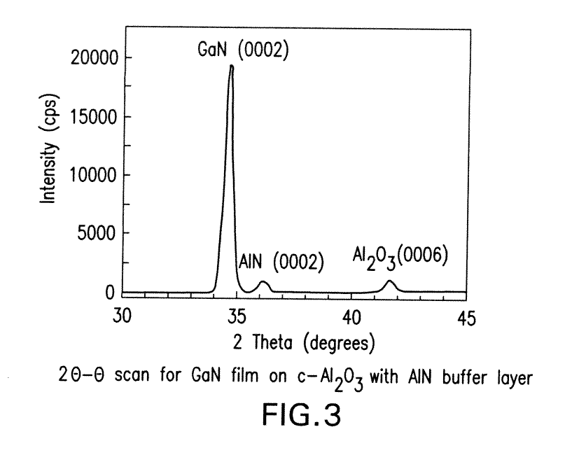

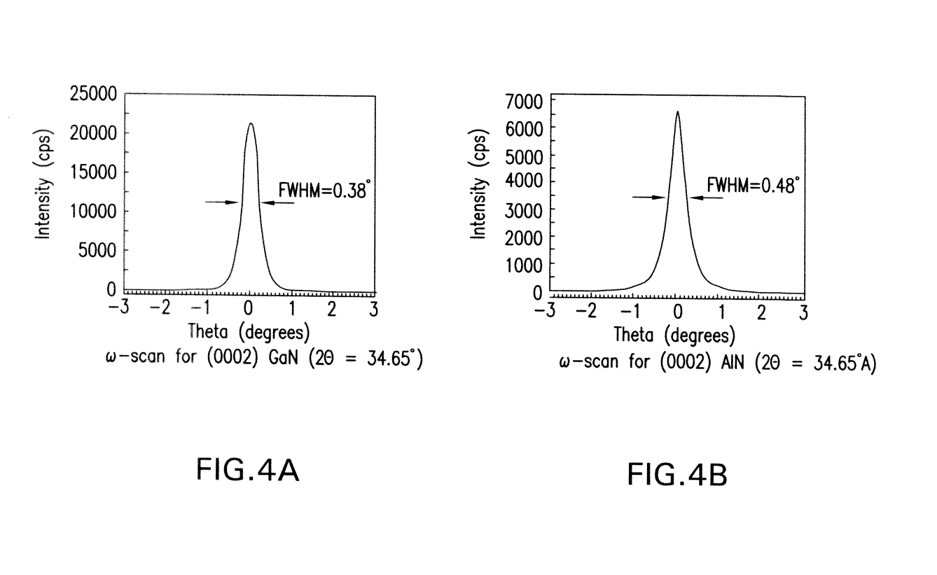

For example, 450 nm thick GaN films fabricated by the Pulsed Laser Deposition of the present invention with the process parameters shown in Table 1 were measured by x-ray diffraction (XRD). The 2θ-θ scan and ω-scans are illustrated by the diagrams presented in FIGS. 3 and 4A-4B, respectively. As shown in FIG. 3, c-axis oriented GaN and AlN peaks are clearly defined at 34.65°, and 36.18° of 2θ-θ scan, respectively. Compared to the Al₂O₃ single crystal peak (2θ=41.75°), the GaN and AlN peaks are strongly intensified suggesting the high quality of GaN and AlN structures.

Referring to FIGS. 4A and 4B, the FWHM (full widths at half maximum) of ω-scans at GaN (0002) and AlN (0002) directions, respectively, were 0.38° and 0.48°, respectively, indicating that GaN and AlN layers are highly c-axis oriented.

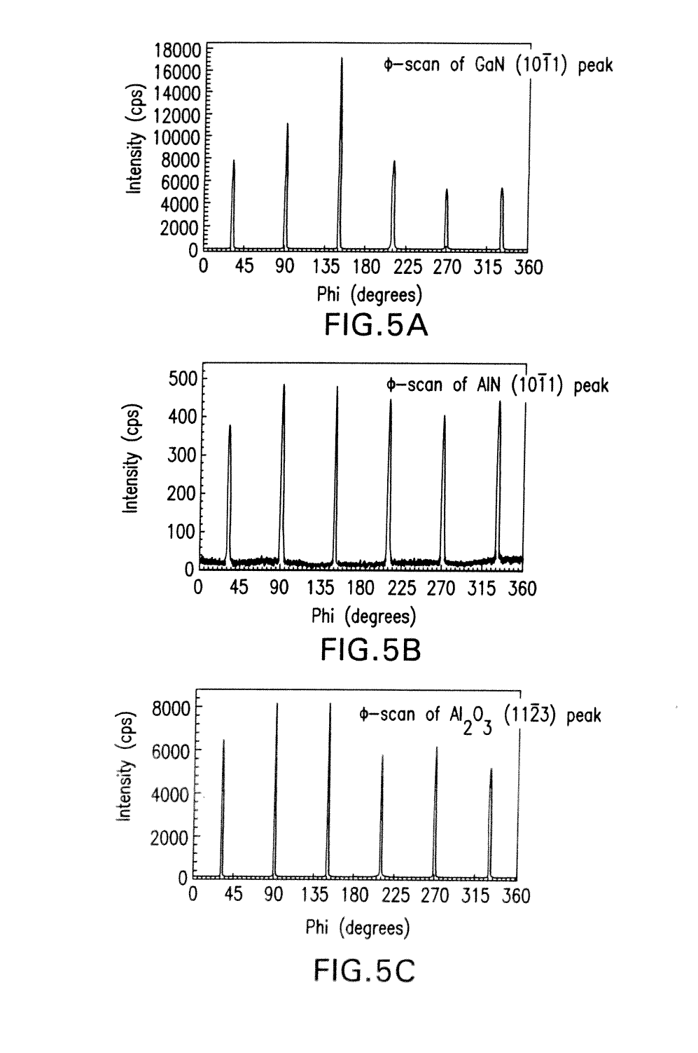

In addition, φ-scans were performed for GaN (10 1̅1), AlN (10 1̅1) and Al₂O₃ (11 2̅3) peaks respectively, as is illustrated in FIGS. 5A, 5B, and 5C. The repeated 60° of peak-to-peak distance indicates the hexagonal structure of film layers. Clear matching peak positions of GaN, AlN and Al₂O₃ confirms that GaN and AlN layers are epitaxially grown on Al₂O₃ substrate.

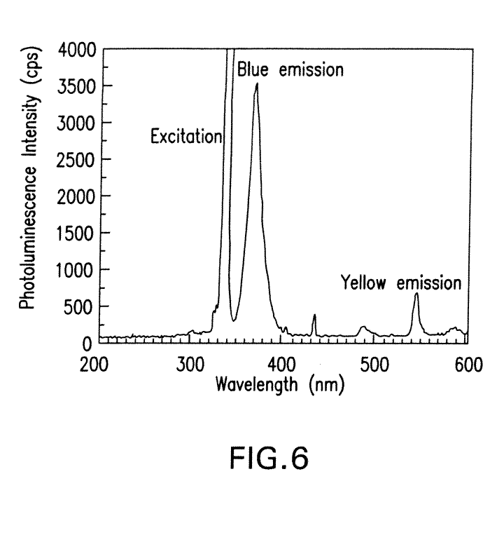

Photoluminescence spectrum of the produced GaN films was measured at room temperatures, as presented in FIG. 6. In this measurement, a nitrogen laser with 340 nm wavelength was used for the exitation beam source. Photoluminescence intensity was then plotted versus the wavelengths. Blue luminescence was detected at 370 nm with strong and well-defined peak. The yellow emission at 545 nm was very weak, which is mainly attributed to structural imperfections, such as grain boundaries or dislocations. The peak-to-peak ratio of blue emission to yellow emission achieved in the GaN films grown by the PLD of the present invention is superior to other results from GaN films processed by CVD, MBE, VPE, PLD and SP, as presented in various prior studies.

Although this invention has been described in connection with specific forms and embodiments thereof, it will be appreciated that various modifications other than those discussed above may be resorted to without departing from the spirit or scope of the invention as defined in the appended claims. For example, equivalent elements may be substituted for those specifically shown and described, certain features may be used independently of other features, and in certain cases, particular locations of the elements may be reversed or interposed, all without departing from the spirit or scope of the invention as defined in the appended claims.

What is claimed is:

1. A method for Pulsed Laser Deposition (PLD) of high quality GaN films, comprising the steps of:
a. positioning a substrate structure in a processing chamber, said substrate structure having a deposition surface;
b. positioning a target in said processing chamber a predetermined distance from said deposition surface of said substrate structure, said target including at least one target material;
c. filling said processing chamber with a reaction gas to a predetermined pressure level;
d. focusing a pulsed laser beam of a predetermined energy density on said target to ablate said at least one target material therefrom, thereby forming a plume of said at least one target material directed towards said deposition surface of said substrate structure; and
e. controlling a plurality of process parameters of the PLD process to attain and maintain plasma energy of said plume of said at least one target material less than 5 eV at said deposition surface.

2. The method of claim 1, wherein said process parameters include, in combination, said predetermined distance between said deposition surface and said target, said predetermined pressure level of said reaction gas in said processing chamber, and said predetermined energy density of said pulsed laser beam.

3. The method of claim 2, wherein said predetermined distance between said deposition surface and said target exceeds 6 inches, wherein said predetermined pressure level of said reaction gas in said processing chamber falls in the range of 5-100 mTorr, and wherein said predetermined energy density of said pulsed laser beam falls in the range of 2-8 J/cm².

4. The method of claim 2, wherein said predetermined distance between said deposition surface and said target is less than 4 inches, wherein said predetermined pressure level of said reaction gas in said processing chamber is approximately higher than 50 mTorr, and wherein said predetermined energy density of said pulsed laser beam is in the range of less than 1.5 J/cm².

5. The method of claim 2, wherein said predetermined distance between said deposition surface and said target falls in the range of 4-6 inches, wherein said predetermined pressure level of said reaction gas in said processing chamber is in the range of 30-150 mTorr, and wherein said predetermined energy density of said pulsed laser beam is in the range of 1-4 J/cm².

6. The method of claim 1, further comprising the step of:
maintaining a temperature of said substrate structure in the range of 400-900° C.

7. The method of claim 1, wherein said at least one material of said target includes Ga or GaN.

8. The method of claim 1, wherein said reaction gas includes N₂, ammonia, or their mixture.

9. The method of claim 1, wherein said substrate structure includes an Al₂O₃ substrate and an AlN buffer layer formed on said Al₂O₃ substrate, and wherein said deposition surface of said substrate structure is defined on an exposed surface of said AN buffer layer.

10. The method of claim 1, wherein said GaN film demonstrates a room temperature intensive sharply-defined blue photoluminescence with negligible imperfection emission.

11. The method of claim 10, wherein the photoluminescence intensity of said blue photoluminescence is approximately 3500 cps at a wavelength of 370 nm, while the photoluminescence intensity of the imperfection emission is approximately 500 cps at the wavelength of 545 nm.

12. A method for fabricating high quality room temperature blue photoluminescence GaN films with a negligible imperfection emission, comprising the steps of:
positioning a target having a target material a predetermined distance from a substrate structure in a processing chamber;
forming a plume of said target material ablated from said target and directed towards said substrate structure to deposit a GaN film thereon; and
maintaining plasma energy of said plume at said substrate structure below 5 eV.

13. The method of claim 12, wherein said GaN film is fabricated by Pulsed Laser Deposition (PLD).

14. The method of claim 12, further comprising the step of:
focusing a pulsed laser beam of a predetermined energy density on said target to form said plume of said target material.

15. The method of claim 14, further comprising the step of:
filling said processing chamber with a reaction gas to a predetermined pressure level.

16. The method of claim 15, further comprising the step of:
controlling, in combination, said predetermined distance between said target and said substrate structure, said predetermined energy density of said pulsed laser beam, and said predetermined pressure level of said reaction gas to maintain said plasma energy of said plume at said substrate structure below said 5 eV.

17. The method of claim 12, wherein said target material includes Ga or GaN.

18. The method of claim 15, wherein said reaction gas includes N₂, ammonia, or their mixture.
